(19) United States
(12) Patent Application Publication
(10) Pub. No.: US 2026/0020390 A1
(43) Pub. Date: Jan. 15, 2026

(54) LIGHT-EMITTING DEVICE AND MANUFACTURING METHOD THEREOF

(71) Applicant: EPISTAR CORPORATION, Hsinchu (TW)

(72) Inventor: Jan-Way CHIEN, Hsinchu (TW)

(21) Appl. No.: 19/267,150

(22) Filed: Jul. 11, 2025

(30) Foreign Application Priority Data
Jul. 12, 2024 (TW) 113126252

(51) Int. Cl. H10H 20/84; H10H 20/819

(52) U.S. Cl. CPC H10H 20/84; H10H 20/819

(57) ABSTRACT

A semiconductor device includes a semiconductor stack and an insulating structure. The semiconductor stack includes an upper surface, a bottom surface and a side surface. The side surface includes first and second sub-side surfaces. A first angle is formed between the first sub-side surface and the upper surface. The first angle is a right angle or an obtuse angle. The second sub-side surface is connected to the bottom surface and a second angle is formed between the second sub-side surface and the bottom surface. The second angle is an obtuse angle. The insulating structure covers the semiconductor stack and includes a first sub-insulating structure and a second sub-insulating structure. The first sub-insulating structure covers the upper surface and the first sub-side surface, and does not cover the second sub-side surface. The second sub-insulating structure covers the upper surface, the first sub-side surface and the second sub-side surface.

### CROSS-REFERENCE TO RELATED APPLICATIONS

This application claims priority to and the benefit of Taiwan patent application No. 113126252 filed on Jul. 12, 2024, and the content of which is incorporated by reference in its entirety.

### BACKGROUND

### Technical Field

The present application relates to a light-emitting device which has a side surface with an insulating structure formed thereon, a backlight unit and a display device having the same.

### Description of the Related Art

Semiconductor devices include compound semiconductors composed of III-V group elements, such as gallium phosphide (GaP), gallium arsenide (GaAs), gallium nitride (GaN), and aluminum nitride (AlN). Semiconductor devices can be semiconductor optoelectronic devices, such as light-emitting diodes (LEDs), lasers, photodetectors, or solar cells, and can also be power devices or acoustic wave devices. Taking the LEDs as an example, the LEDs in solid-state light-emitting devices have advantages such as low power consumption, low heat generation, long lifetime, compact size, high response speed, and good optoelectronic properties, such as stable light emission wavelength. Thus, the LEDs have been widely used in household devices, indicator lights, and optoelectronic products.

Conventional LED includes a substrate, an n-type semiconductor layer, an active layer and a p-type semiconductor layer formed on the substrate, and a p-electrode and an n-electrode formed on the p-type and the n-type semiconductor layers, respectively. When light-emitting diode is conducted through the electrode and operates under a specific forward bias, holes from the p-type semiconductor layer and electrons from the n-type semiconductor layer combine in the active layer to emit light. While the light-emitting diodes are incorporated into various optoelectronic products whose volumes are getting smaller, a smaller size of the light-emitting diode with qualified photoelectric characteristics and manufacturing yield is also desired.

### SUMMARY OF THE DISCLOSURE

A semiconductor device, includes: a semiconductor stack, including an upper surface, a bottom surface and a side surface, wherein: the side surface includes a first sub-side surface and a second sub-side surface; a first angle is formed between the first sub-side surface and the upper surface, the first angle is a right angle or an obtuse angle; and the second sub-side surface is connected to the bottom surface and a second angle is formed between the second sub-side surface and the bottom surface, the second angle is an obtuse angle; and an insulating structure, covering the semiconductor stack; wherein the insulating structure includes a first sub-insulating structure and a second sub-insulating structure; wherein the first sub-insulating structure covers the upper surface and the first sub-side surface, and does not cover the second sub-side surface; and wherein the second sub-insulating structure covers the upper surface, the first sub-side surface and the second sub-side surface.

A semiconductor device includes: a semiconductor stack, including an upper surface, a bottom surface and a side surface; wherein: the side surface includes a first sub-side surface and a second sub-side surface; a first angle is formed between the first sub-side surface and the upper surface, the first angle is a right angle or an obtuse angle; and the second sub-side surface is connected to the bottom surface and a second angle is formed between the second sub-side surface and the bottom surface, the second angle is an obtuse angle; and an insulating structure, covering the semiconductor stack, including a first sub-insulating structure; wherein: the first sub-insulating structure covers the upper surface and the first sub-side surface, and does not cover the second sub-side surface; and the first sub-insulating structure includes a first side surface located on the first sub-side surface, the first side surface is substantially parallel to the second sub-side surface.

### BRIEF DESCRIPTION OF THE DRAWINGS

FIGS. 1A to 1H show a manufacturing method of a light-emitting device 1 in accordance with an embodiment of the present application.

FIG. 2A shows a plan view of the light-emitting device 1.

FIG. 2B shows a cross-sectional view of the light-emitting device 1 and a partial enlarged view thereof.

FIG. 3 shows an enlarged cross-sectional view of a light-emitting device 2 in accordance with another embodiment of the present application.

FIG. 4 shows an enlarged cross-sectional view of a light-emitting device 3 in accordance with another embodiment of the present application.

FIG. 5 shows a cross-sectional view and an enlarged cross-sectional view of a light-emitting device 4 in accordance with another embodiment of the present application.

FIGS. 6A to 6D each shows a partially enlarged cross-sectional view of a light-emitting device 6 in accordance with another embodiment of the present application.

FIG. 7 shows a cross-sectional view of a light-emitting device 7 in accordance with another embodiment of the present application.

FIG. 8 shows a cross-sectional view of a light-emitting device 9 in accordance with another embodiment of the present application.

FIGS. 9A to 9C show a manufacturing method of the light-emitting device 9 in accordance with an embodiment of the present application.

FIG. 10 shows a plan view of a light-emitting device in accordance with another embodiment of the present application.

FIGS. 11A to 11E show a manufacturing method of a light-emitting device 11 in accordance with an embodiment of the present application.

FIG. 12 shows a cross-sectional view and an enlarged cross-sectional view of the light-emitting device 11 in accordance with another embodiment of the present application.

FIG. 13A shows a partially enlarged cross-sectional view of a light-emitting device 11′ in accordance with another embodiment of the present application.

FIG. 13B shows a plan view viewing from a light-extraction surface of the light-emitting device 11′.

FIG. 13C shows an enlarged cross-sectional view of the light-emitting device 11′ in accordance with another embodiment of the present application.

FIG. 14 shows a cross-sectional view of a light-emitting device 13 in accordance with another embodiment of the present application.

FIG. 15 shows a manufacturing method of the light-emitting device 1 in accordance with another embodiment of the present application.

FIG. 16 shows a cross-sectional view of a light-emitting module 100 in accordance with an embodiment of the present application.

FIG. 17 shows a schematic diagram of a display module 105 which includes the light-emitting device in accordance with any embodiments of the present application.

### DETAILED DESCRIPTION

In order to make the description of the present application more detailed and complete, please refer to the description of the following embodiments and cooperate with the relevant illustrations. The examples shown below are used to illustrate the semiconductor device of the present application, the semiconductor devices in some embodiments can be a semiconductor optoelectronic device such as a light emitting diode (LED), a laser, a photodetector, a solar cell, or a power device. The main structure of the semiconductor device includes a buffer layer and a device structure formed on the buffer layer, where the device structure varies depending on the function of the semiconductor device.

For example, in the case of a light emitting device, it includes a semiconductor light-emitting stack with a p-type semiconductor layer, an n-type semiconductor layer and an active region, wherein the active includes a light-emitting layer, which can emit different wavelengths of light depending on the material composition.

Furthermore, unless otherwise specified, the sizes, materials, shapes, relative arrangements, etc. of the components described in the embodiments in this specification do not limit the scope of the present application and are merely described for explanation. The size or positional relationships of components shown in the drawings may be exaggerated for clarity. In the following descriptions, for brevity, the same names and symbols are used for the same or similar components.

In the present application, unless otherwise specified, the formula AlGaN represents AlₐGa₍₁₋ₐ₎N, where 0≤a≤1; the formula InGaN represents In_{b}Ga_{(1-b)}N, where 0≤b≤1; the formula AlInGaN represents Al_{c}In_{d}Ga_{(1-c-d)}N, where 0≤c≤1, 0≤d≤1. The formula AlInGaP represents (AlₑIn₍₁₋ₑ₎)_{1-f}Ga_{f}P, where 0≤e≤1, 0≤f≤1; the formula InGaAsP represents In_{g}Ga_{1-g}AsₕP₁₋ₕ, where 0≤g≤1, 0≤h≤1. Adjusting the content of the elements can achieve different purposes, including but not limited to adjusting energy levels or tuning the main emission wavelength of the light-emitting device.

The composition and dopants of each layer included in the semiconductor device illustrated in the present application can be analyzed by any suitable method, such as secondary ion mass spectrometry (SIMS).

The width or thickness of each layer or structure included in the semiconductor device illustrated in the present application can be analyzed by any suitable method, such as transmission electron microscopy (TEM) or scanning electron microscopy (SEM).

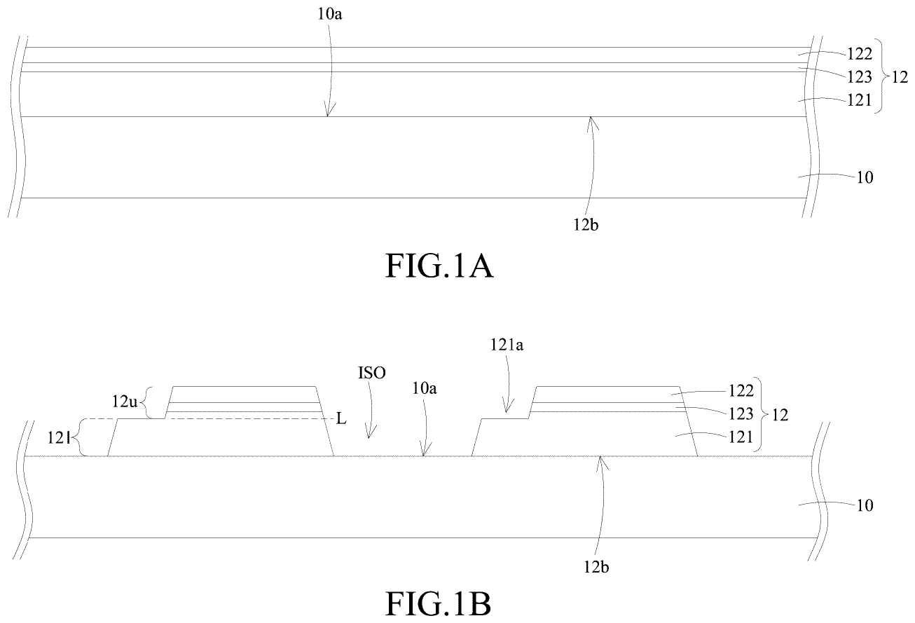

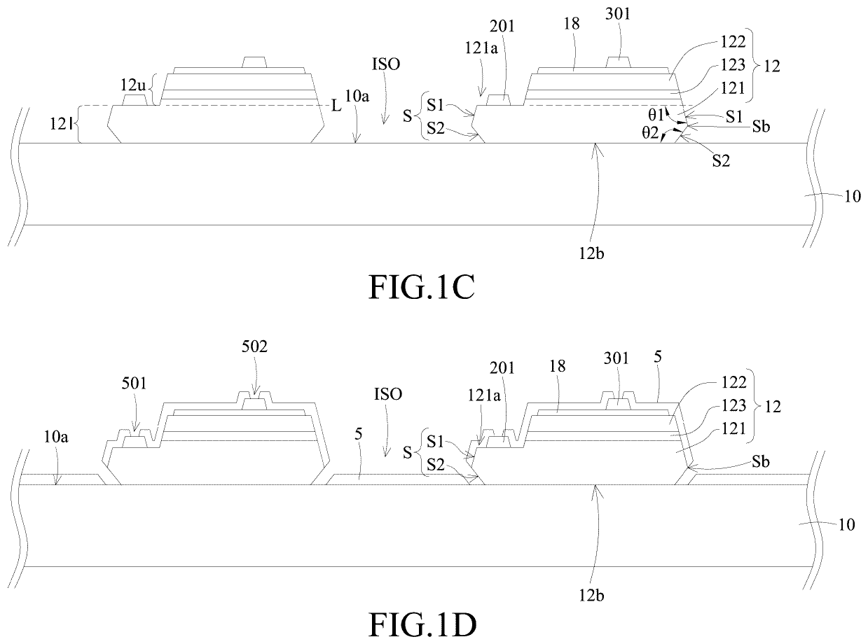

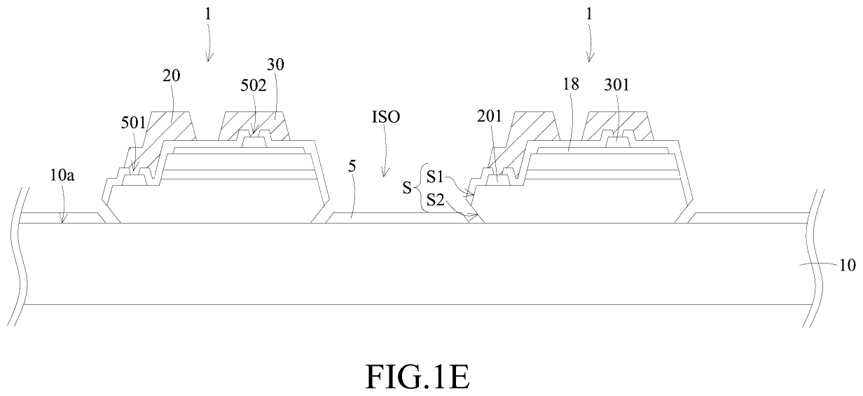

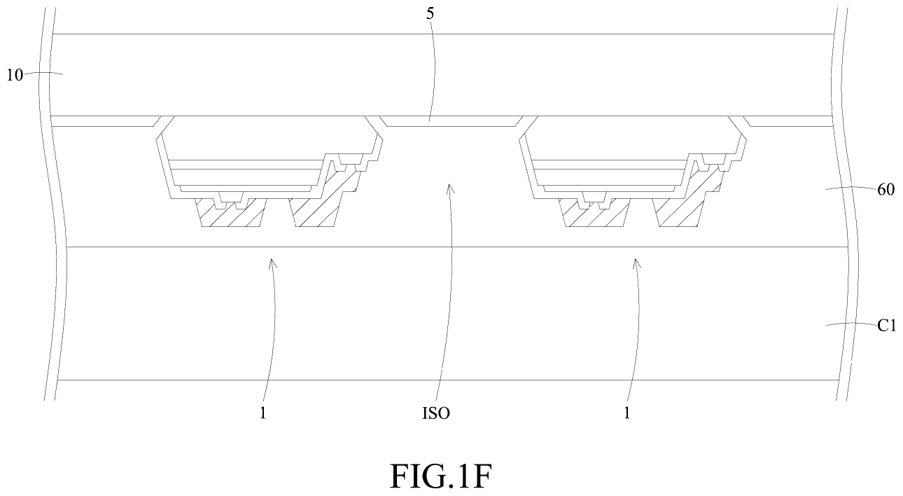

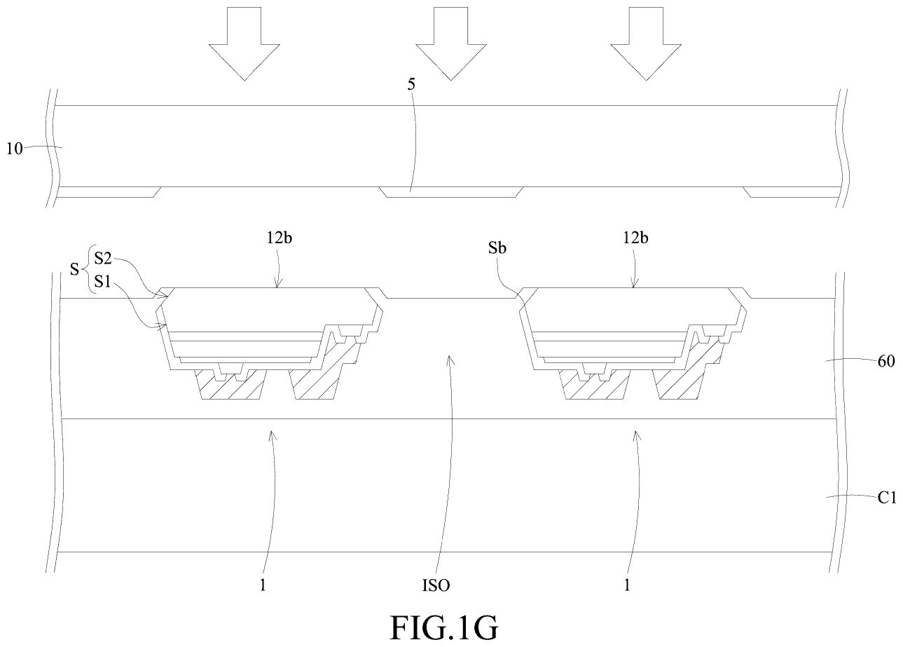

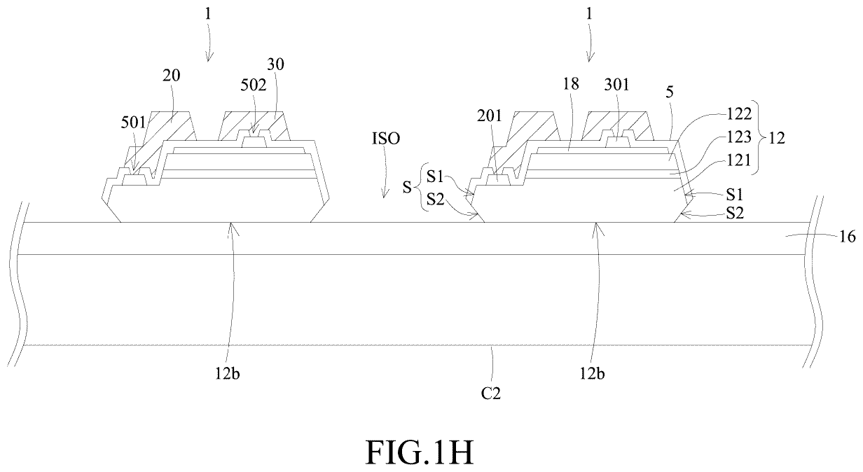

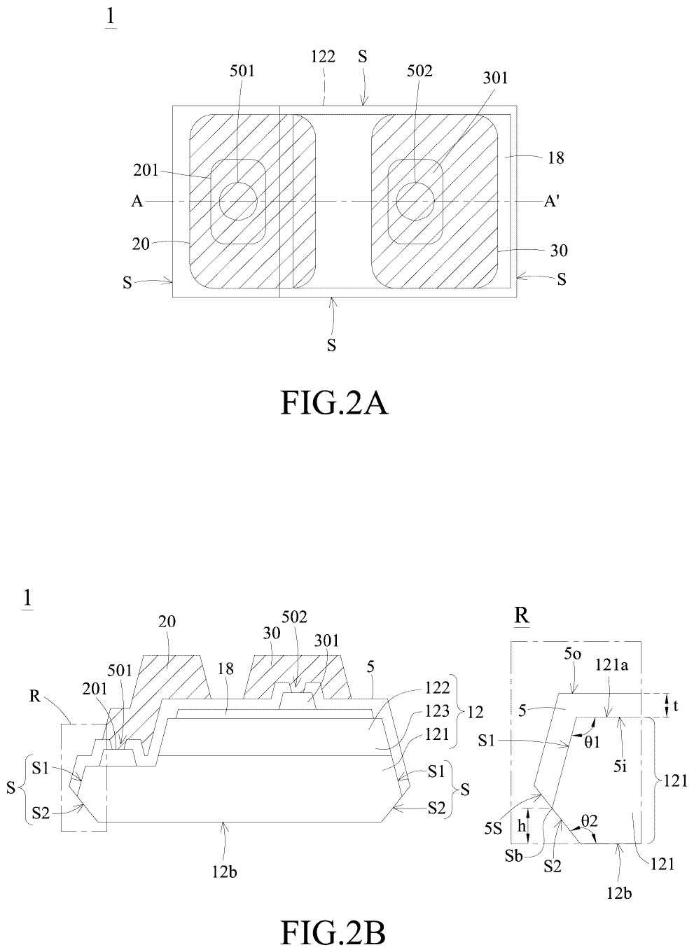

In detail, each of the following embodiments uses a light-emitting device as an example of a semiconductor device for explanation. FIG. 2 shows a plan view of a light-emitting device 1 in accordance with an embodiment of the present application. FIG. 2B shows a cross-sectional view taken along an A-A′ line in FIG. 1A and a partial enlarged view. FIGS. 1A to 1H show a manufacturing method of the light-emitting device 1 in accordance with an embodiment of the present application. First, referring to FIG. 1A, a semiconductor stack 12 is formed on an upper surface 10a of a substrate 10. In one embodiment, the substrate 10 can be a growth substrate. The substrate 10 includes GaAs or GaP for growing AlGaInP semiconductor thereon. The substrate 10 includes Al₂O₃, GaN, SiC or AlN for growing InGaN or AlGaN semiconductor thereon. The substrate 10 can be a planar substrate or a patterned substrate. The patterned substrate includes patterned structures (not shown) on the upper surface 10a. The patterned structure may be a plurality of recesses (not shown) recessed into the substrate 10 or a plurality of protrusions (not shown) protruding upward. In one embodiment, the patterned structure is formed by partially etching a surface of the substrate 10 by mechanical grinding, dry etching or wet etching. In another embodiment, the patterned structure is formed by forming a layer which has a material different from that of the substrate 10 on the upper surface 10a of the substrate 10, and then patterning the layer to form the protrusions. The shape of the protrusion includes pyramid, hemispherical, conical, strip or polygonal shapes, etc. The shape of the recess includes pyramid, hemispherical, conical, groove or polygonal structures, etc. The plurality of recesses or the plurality of protrusions can be regularly distributed or irregularly distributed. In different embodiments, the plurality of protrusions can be separated or connected to each other. The plurality of recesses can be separated or connected to each other.

In one embodiment of the present application, the method for forming the semiconductor stack 12 on the substrate 10 includes metal-organic chemical vapor deposition (MOCVD), molecular beam epitaxy (MBE), hydride vapor phase epitaxy (HVPE), or ion plating, such as sputtering or evaporation, etc.

The semiconductor stack 12 includes a first semiconductor layer 121, an active region 123 and a second semiconductor layer 122. In one embodiment, the semiconductor stack 12 further includes a buffer structure (not shown) between the first semiconductor layer 121 and the substrate 10. The buffer structure reduces the lattice mismatch and suppresses dislocation so as to improve the epitaxy quality. The material of the buffer structure includes GaN, AlGaN, or AlN. In an embodiment, the buffer structure 120 includes a plurality of sub-layers (not shown) and the sub-layers include the same materials or different materials. In one embodiment, the first semiconductor layer 121 and the second semiconductor layer 122 are, for example, cladding layers or confinement layers. The first semiconductor layer 121 and the second semiconductor layer 122 have different conductivity types, different electrical properties, different polarities or different dopants for providing electrons or holes. For example, the first semiconductor layer 121 includes n-type semiconductor and the second semiconductor layer 122 includes p-type semiconductor. The active region 123 is formed between the first semiconductor layer 121 and the second semiconductor layer 122. When being driven by a current, electrons and holes are combined in the active region 123 to convert electrical energy into optical energy for illumination. The wavelength of the light generated by the light-emitting device 1 or by the semiconductor stack 12 can be adjusted by changing the physical properties and chemical composition of one or more layers in the semiconductor stack 12.

The material of the semiconductor stack 12 includes III-V compound semiconductor such as AlₓIn_{y}Ga_{(1-x-y)}N (i.e. AlInGaN) or AlₓIn_{y}Ga_{(1-x-y)}P (i.e. AlInGaP), where 0≤x, y≤1; x+y≤1. When the semiconductor stack 12 includes AlInGaP, the semiconductor stack 12 emits red light having a wavelength between 610 nm and 650 nm or yellow light having a wavelength between 550 nm and 570 nm. When the semiconductor stack 12 includes AlInGaN, the semiconductor stack 12 emits blue light or deep blue light having a wavelength between 400 nm and 490 nm, green light having a wavelength between 490 nm and 550 nm or UV light having a wavelength between 250 nm and 400 nm. The semiconductor stack 12 includes a single hetero-structure (SH), a double hetero-structure (DH), a double-side double hetero-structure (DDH), or a multi-quantum well (MQW) structure. The material of the active region 123 can be i-type, p-type or n-type semiconductor.

Next, part of the semiconductor stack 12 is removed. Referring to FIG. 1B, removing part of the semiconductor stack 12 may include removing one part of the semiconductor stack 12 to form an ISO region and removing another part of the semiconductor stack 12 to expose an upper surface 121a of the first semiconductor layer 121. The order of forming the ISO region and the upper surface 121a of the first semiconductor layer 121 can be adjusted according to process requirements. The ISO region divides the semiconductor stack 12 into a plurality of semiconductor units. The upper surface 121a of the first semiconductor layer 121 is not covered by the active region 123 and the second semiconductor layer 122. In a side view or a cross-sectional view, the semiconductor stack 12 above a virtual extending plane L (or a virtual extending line) of the upper surface 121a is named upper semiconductor stack 12u, and the semiconductor stack 12 below the virtual extending plane L is named lower semiconductor stack 121. The upper semiconductor stack 12u includes the second semiconductor layer 122 and the active region 123. In one embodiment, the upper semiconductor stack 12u further includes a portion of the first semiconductor layer 121. The lower semiconductor stack 121 includes the entirety portion or another portion of the first semiconductor layer 121 and a buffer structure. In one embodiment, the bottom of the ISO region includes the upper surface 10a of the substrate 10. In another embodiment, the bottom of the ISO region includes an upper surface of the buffer structure (not shown). The method of removing the semiconductor stack 12 includes, for example, etching. In another embodiment, a bonding layer (not shown) is formed between the semiconductor stack 12 and the substrate 10. The step of forming the ISO region includes removing a portion of the semiconductor stack 12 and removing a portion of the bonding layer to form the bottom of the ISO region, that is, to expose the upper surface 10a of the substrate 10. The method of removing a portion of the bonding layer includes, for example, etching. The methods of removing the semiconductor stack 12 and removing the bonding layer can be the same or different.

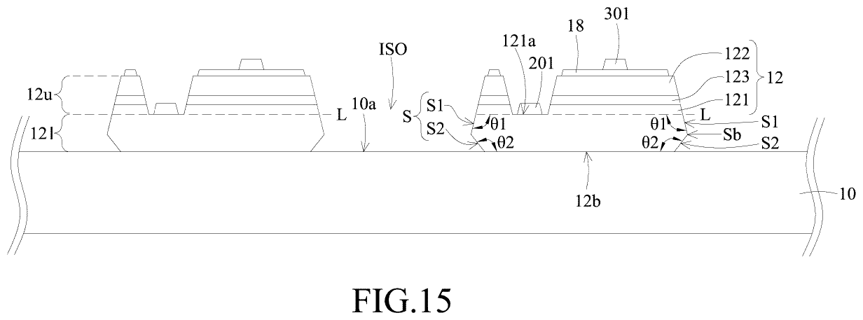

Next, referring to FIG. 1C, an etching step is performed on the exposed semiconductor stack 12. In one embodiment, the semiconductor stack 12 includes AlInGaN materials, and the etching is preformed by, for example, wet etching to further remove a portion of the lower semiconductor stack 121 exposed in the ISO region, to form a side surface S of the semiconductor stack 12. The side surface S includes a first sub-side surface S1 and a second sub-side surface S2. In one embodiment, as shown in FIG. 1C, the first sub-side surface S1 is connected to the upper surface 121a of the first semiconductor layer 121, and a first angle θ1 is formed therebetween. The second sub-side surface S2 is connected to a bottom surface 12b of the semiconductor stack 12, and a second angle θ2 is formed therebetween. The first angle θ1 is a right angle or an obtuse angle, and the second angle θ2 is an obtuse angle. The first sub-side surface S1 and the second sub-side surface S2 are connected at a boundary Sb. In addition, as shown in a right side of the semiconductor stack 12 in FIG. 1C, the first sub-side surface S1 can be connected to the upper surface of the second semiconductor layer 122, and a right angle or an obtuse angle is formed between the first sub-side surface S1 and the upper surface of the second semiconductor layer 122. In another embodiment shown in FIG. 15, depending on positions of the upper surface 121a of the first semiconductor layer 121, the first sub-side surface S1 is not directly connected to the upper surface 121a, and the first angle θ1 is formed between the first sub-side surface S1 and a virtual extending surface L of the upper surface 121a. Both embodiments can be regarded as forming the first included angle θ1 between the first sub-side surface S1 and the upper surface 121a. In one embodiment, the second angle θ2 is between 100-160 degrees. In one embodiment, the etching solution applied in this etching step includes sulfuric acid, phosphoric acid, etc.

Next, a transparent conductive layer 18 and contact electrodes 201 and 301 can be optionally formed on the second semiconductor layer 122. The transparent conductive layer 18 can spread current and provide good electrical contact with the second semiconductor layer 122, such as ohmic contact. The transparent conductive layer 18 is transparent to the light emitted from the active region 123. For example, the transparent conductive layer 18 has a transmittance of more than 80% to the light emitted from the active region 123. The material of the transparent conductive layer 18 can be a metal or a transparent metal oxide or graphene. The metal material includes Au, NiAu, etc. The transparent metal oxide includes ITO, AZO, GZO, ZnO, IZO, etc. The contact electrode includes a first contact electrode 201 located on the upper surface 121a of the first semiconductor layer 121, and/or a second contact electrode 301 located on the second semiconductor layer 122 or the transparent conductive layer 18. The first contact electrode 201 and the second contact electrode 301 are electrically connected to the first semiconductor layer 121 and the second semiconductor layer 122, respectively. The contact electrode includes metal, such as chromium (Cr), titanium (Ti), tungsten (W), gold (Au), aluminum (Al), rhodium (Rh), indium (In), tin (Sn), nickel (Ni), platinum (Pt), copper (Cu), silver (Ag), a laminated stack or an alloy of the above metals. In one embodiment, the first contact electrode 201 and the second contact electrode 301 can be formed in the same process or in different processes, and can include the same or different materials. In another embodiments, the transparent conductive layer 18 and/or any one of the contact electrodes can be omitted.

Next, referring to FIG. 1D, an insulating structure 5 is formed on the semiconductor stack 12 and the ISO region. The insulating structure 5 may further cover the contact electrodes 201, 301 and the transparent conductive layer 18. A first opening 501 and a second opening 502 are formed in the insulating structure 5. In one embodiment, the first opening 501 is located on the first contact electrode 201 and exposes the first contact electrode 201, and the second opening 502 is located on the second contact electrode 301 and exposes the second contact electrode 301. In another embodiment, when the contact electrode is not formed, the first opening 501 may expose the first semiconductor layer 121, and the second opening 502 may expose the transparent conductive layer 18 or the second semiconductor layer 122.

In one embodiment, referring to FIG. 1D, the insulating structure 5 is partially formed on the side surface S of the semiconductor stack 12, for example, formed on the first sub-side surface S1. In the step of forming the insulating structure 5, the insulating structure 5 may cover the first sub-side surface S1 and partially cover the second sub-side surface S2 or not cover the second sub-side surface S2, so that parts of the second sub-side surface S2 close to the substrate 10 is exposed and not covered by the insulating structure 5. In one embodiment, the height of the boundary Sb relative to the bottom surface 12b of the semiconductor stack 12 can be controlled by controlling the etching conditions of the lower semiconductor stack 121. Because the second sub-side surface S2 is provided and the boundary Sb has the height relative to the bottom surface 12b of the semiconductor stack 12 or the upper surface 10a of the substrate 10, the insulating structure 5 can be disconnected near the boundary Sb and becomes discontinuous. Therefore, as shown in FIG. 1D, the insulating structure 5 is formed on the first sub-side surface S1 and the upper surface 10a in the ISO region, but not on the second sub-side surface S2. In other words, the insulating structure 5 covers the first sub-side surface S1 but does not cover the second sub-side surface S2. In one embodiment, the insulating structure 5 further covers the upper surface of the semiconductor stack 12, including the upper surface 121a of the first semiconductor layer 121 and the upper surface of the second semiconductor layer 122.

The insulating structure 5 can be a stack of multiple insulating layers or a single insulating layer, and its material includes insulating materials, such as silicon oxide, silicon nitride, silicon oxynitride, niobium oxide, hafnium oxide, titanium oxide, magnesium fluoride, aluminum oxide, etc. In the embodiment which the insulating structure 5 includes a stack of multiple insulating layers, the insulating structure 5 includes one or more pairs of insulating layers, wherein one pair of the insulating layers is composed by a first sub-layer and a second sub-layer (not shown) having different refractive indexes. By selecting materials with different refractive index and the thicknesses thereof, the insulating structure 5 can reflect lights within a pre-defined wavelength range or a pre-defined incident angle. In one embodiment, the first sub-layer 51a has a smaller thickness than the second sub-layer 51b. In one embodiment, the insulating structure 5 includes distributed Bragg reflector. For example, the insulating structure 5 has a reflectance of more than 60% of the dominant wavelength and/or the peak wavelength of the semiconductor stack 12.

In another embodiment, the insulating structure 5 further includes additional layers other than the first sub-layer and the second sub-layer. For example, the insulating structure 5 further includes a bottom layer (not shown) between the first sub-layer and the second sub-layer and the semiconductor stack 12. In other words, the bottom layer is formed on the semiconductor stack 12 first, and then the first sub-layers and the second sub-layers are formed on the bottom layer. In one embodiment, the bottom layer can protect the light-emitting device or the semiconductor stack. For example, the bottom layer prevents moisture from penetrating the light-emitting device. In one embodiment, the bottom layer includes insulating material which is the same as one of the first sub-layer and the second sub-layer or different from both the first sub-layer and the second sub-layer. The thickness of the bottom layer is greater than those of the first sub-layer and the second sub-layer. In one embodiment, the bottom layer can be formed by a process different from that for forming the first sub-layer and the second sub-layer. For example, the bottom layer is formed by CVD, and preferably, formed by plasma enhanced chemical vapor deposition (PECVD). The first sub-layer and the second sub-layer are formed by PVD, such as evaporation or sputtering. In another embodiment, the bottom layer can be formed by a process same as that for forming the first sub-layer and the second sub-layer. For example, the bottom layer, the first sub-layer and the second sub-layer are formed by chemical vapor deposition (CVD) or physical vapor deposition (PVD). For example, the bottom layer, the first sub-layer and the second sub-layer are formed by PVD, such as evaporation, sputtering, or the combination thereof, to get a smoother surface of the insulating structure 5.

In another embodiment, the insulating structure 5 further includes a top layer (not shown) on sides of the first sub-layer and the second sub-layers opposite to the second semiconductor 122. In other words, the first sub-layer and the second sub-layer are formed on the semiconductor stack 12 first, and then the top layer is formed. The top layer can improve the robustness of the insulating structure 5. For example, when the insulating structure 5 is subject to an external force, the top layer can prevent the insulating structure 5 from being broken and damaged due to the external force. The top layer includes insulating material, which can be the same as one of the first sub-layer and the second sub-layer or different from both the first sub-layer and the second sub-layer. The thickness of the top layer is greater than the thickness of the first sub-layer and the second sub-layer. Like the bottom layer, the method of forming the top layer can be different from that of the first sub-layer and the second sub-layer, or the same as that of the first sub-layer and the second sub-layer. In another embodiment, the insulating structure 5 includes a stack composed of the first sub-layer(s) and the second sub-layer(s), and any one of the bottom layer and the top layer.

Next, referring to FIG. 1E, a first electrode pad 20 and a second electrode pad 30 are formed on the insulating structure 5. The first electrode pad 20 fills the first opening 501 and is electrically connected to the first semiconductor layer 121, and the second electrode pad 30 fills the second opening 502 and is electrically connected to the second semiconductor layer 122. The first electrode pad 20 and the second electrode pad 30 include metals, such as chromium (Cr), titanium (Ti), tungsten (W), gold (Au), aluminum (Al), indium (In), tin (Sn), nickel (Ni), platinum (Pt), copper (Cu), silver (Ag), a stack or an alloy of the above metals. The first electrode pad 20 and the second electrode pad 30 can serve as a current path for an external power source to supply power to the first semiconductor layer 121 and the second semiconductor layer 122.

Next, referring to FIG. 1F, a first bonding step is performed. The light-emitting device 1 and the substrate 10 are bonded to a first carrier C1 by a first bonding layer 60. The first bonding layer 60 can fill in the ISO region. The material of the first bonding layer 60 can be a polymer, such as polyimide (PI), epoxy, polybenzoxazole (PBO), silicone, acrylic resin, cycloolefin polymer (COC or COP), or benzocyclobutane (BCB), etc. In one embodiment, the first bonding layer 60 is transparent to the light emitted by the semiconductor stack 12. In another embodiment (not shown), the insulating structure 5 in the ISO region can be removed from the substrate 10 in the step shown in FIG. 1D or FIG. 1E, then the first bonding step shown in FIG. 1F is performed.

Next, referring to FIG. 1G, a step of removing the substrate 10 is performed to expose the bottom surface 12b of the semiconductor stack 12. The method of removing the substrate 10 includes but is not limited to laser. In one embodiment, the insulating structure 5 on the first bonding layer 60 in the ISO region can be removed while removing the substrate 10. In another embodiment, the insulating structure 5 in the ISO region is completely removed while removing the substrate 10, and the insulating structure 5 on the first bonding layer 60 in the ISO region can be further removed after removing the substrate 10. In another embodiment, the insulating structure 5 in the ISO region can be removed before performing the first bonding step, so that when the first bonding step is performed and the substrate 10 is removed, the insulating structure 5 no longer exists in the ISO region.

In other embodiments (not shown), after removing the substrate 10, the bottom surface 12b of the semiconductor stack 12 may be subjected to other treatments, such as grinding, polishing, or etching, and the bottom surface 12b can includes a flat surface, an arc-shaped convex surface, a concave surface, or a structured surface. The structured surface can be, for example, an irregular rough structure or a regular patterned structure. For the convenience of description, the treated bottom surface of the semiconductor stack is also referred to as the bottom surface 12b of the semiconductor stack 12 in the present specification.

In the step of forming the insulating structure 5 shown in FIG. 1D, the insulating structure 5 is disconnected near the boundary Sb, and the part of the insulating structure 5 located on the ISO region is disconnected with another part of the insulating structure 5 covering the semiconductor stack 12. At the boundary of the side surface S of the semiconductor stack 12 and the upper surface 10a of the substrate 10, i.e. the boundary of the second sub-side surface S2 and the upper surface 10a of the substrate, there is no insulating structure 5. In a comparative example, the side surface of the semiconductor stack does not have the second sub-side surface as described in the embodiment, and a continuous film is formed on the side surface of the semiconductor stack and the upper surface of the substrate, that is, a continuous film exists at the boundary of the side surface of the semiconductor stack and the upper surface of the substrate. This continuous film can be, for example, a continuous insulating layer. While removing the substrate, the continuous film adheres to the upper surface of the substrate. A pulling force between the continuous film and the upper surface of the substrate may further damage the film on the semiconductor stack. After removing the substrate 10, the film on the ISO region may keep attaching and extending to the semiconductor stack, reducing the manufacturing yield of the light-emitting device. The thicker the continuous film, the more significant the above problem. The manufacturing method of the light-emitting device in accordance with the embodiment of the present application can avoid the problem existing in the comparative example.

Next, referring to FIG. 1H, a second bonding step is performed. The bottom surface 12b of the semiconductor stack 12 is bonded to the second carrier C2 by a second bonding layer 16, and then the first carrier C1 and the first bonding layer 60 are removed. The material of the second bonding layer 16 can be selected from the material of the first bonding layer 60 described above, and will not be described in detail here. In one embodiment, before the second bonding step is performed, the first bonding layer 60 in the ISO region shown in FIG. 1G can be removed.

After the second bonding step, one or more transfer steps may be optionally performed to transfer the light-emitting device 1 from the second carrier C2 to a driving backplane of an end product (not shown). The light-emitting device 1 can be fixed on the driving backplane and the first electrode pad 20 and the second electrode pad 30 of the light-emitting device 1 are bonded and electrically connected to a circuit on the driving backplane. The bonding method includes eutectic bonding, welding bonding or conductive adhesive bonding. The circuit on the driving backplane is used to control the light-emitting device 1. The end product includes lighting device or display device, and the circuit includes but is not limited to active electronic components, such as transistors.

FIG. 2A shows a plan view of the light-emitting device 1 obtained by the manufacturing method in accordance with the above embodiment of the present application. FIG. 2B shows a cross-sectional view of the light-emitting device 1 taken along AA′ line and a partial enlarged view of a region R thereof. As shown in FIG. 2B, the insulating structure 5 covers the first sub-side surface S1, but does not cover the second sub-side surface S2. The first electrode pad 20 fills the first opening 501 of the insulating structure 5 and is electrically connected to the first semiconductor layer 121. The second electrode pad 30 fills the second opening 502 of the insulating structure 5 and is electrically connected to the second semiconductor layer 122. The light emitted from the semiconductor stack 12 can be extracted from the bottom surface 12b of the semiconductor stack 12. The insulating structure 5 includes an inner surface 5i contacting the semiconductor stack 12, an outer surface 5o opposite to the inner surface 5i, and a side surface 5S located between the inner surface 5i and the outer surface 5o. The side surface 5S is located on the first sub-side surface S1 and adjacent to the boundary Sb. In one embodiment, the side surface 5S is substantially parallel to the second sub-side surface S2. The insulating structure 5 has a thickness t. The thickness of the insulating structure 5 located on the upper surface 121a of the first semiconductor layer and the upper surface of the second semiconductor layer 122 can be greater than the thickness of the insulating structure 5 on the first sub-side surface S1. The boundary Sb has a height h relative to the bottom surface 12b of the semiconductor stack 12. The height h can also be regarded as the vertical distance of the boundary Sb to the bottom surface 12b of the semiconductor stack 12. In one embodiment, the height h is greater than or equal to the thickness t. In this way, in the process of forming the insulating structure 5, the insulating structure 5 is easily disconnected near the boundary Sb to form a discontinuity.

It should be noted that although FIG. 2 shows an enlarged view of a local area R on the left side of the light-emitting device 1, a person skilled in the art can understand from the disclosure of the embodiments that the side surface S of the semiconductor stack 12 in other region of the light-emitting device 1, such as right side, also has the same structure. In any embodiment of the light-emitting device in the present application, the enlarged view of the local area R is equally applicable as described above.

In different embodiments, the bottom surface 12b of the semiconductor stack 12 can be planar or curved (not shown), wherein the curved surface may be convex outward or concave inward. The curved surface may be formed by processing the bottom surface 12b of the semiconductor stack 12 after the step of removing the substrate 10 in FIG. 1G, for example, polishing the bottom surface 12b of the semiconductor stack. In one embodiment, the curved bottom surface 12b of the semiconductor stack 12 can change propagation direction of light, thereby achieving the effect of adjusting the light pattern of the light-emitting device. In one embodiment, the bottom surface 12b of the semiconductor stack 12 can include multiple convex lenses or concave lenses formed by a plurality of the curved surfaces.

If the details of each elements of the light-emitting devices in different embodiments disclosed in the present application, such as material, thickness, function, are not specifically described in each embodiment and have the same name and same label as those of the light-emitting device 1, the details can be referred to the description of the light-emitting device 1, and will not be repeated.

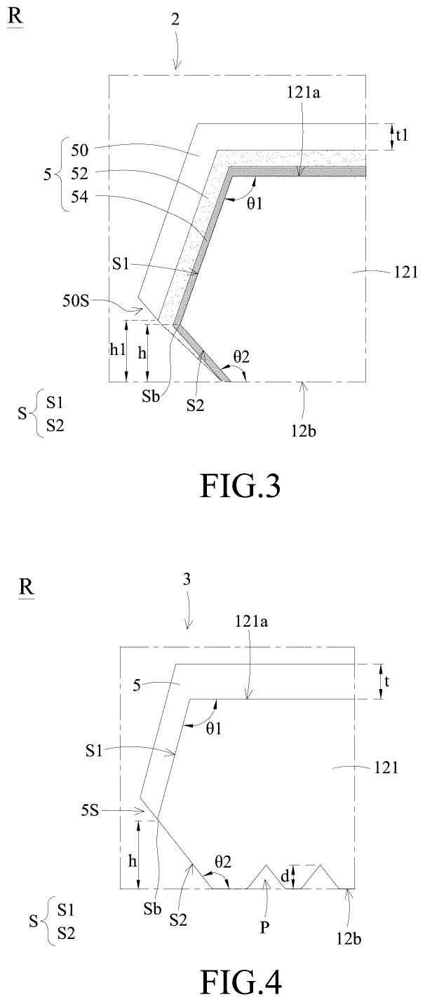

FIG. 3 shows an enlarged cross-sectional view of a local area R of a light-emitting device 2 in accordance with another embodiment of the present application. In order to show the difference between the light-emitting device 2 and the light-emitting device 1, the enlarged cross-sectional view of a local area R is used for explanation. The parts of the structure of the light-emitting device 2 that are the same as those of the light-emitting device 1 are not shown in a full cross-sectional view. The difference between the light-emitting device 2 and the light-emitting device 1 is that the insulating structure 5 of the light-emitting device 2 includes a first sub-insulating structure 50, a second sub-insulating structure 52 and a third sub-insulating structure 54. By selecting different methods to form the sub-insulating structures in the insulating structure 5, different capping structures on the side surface S of the semiconductor stack 12 can be obtained. In one embodiment, the first sub-insulating structure 50 covers the first sub-side surface S1 but does not cover the second sub-side surface S2. The first sub-insulating structure 50 includes a side surface 50S located on the first sub-side surface S1, adjacent to the boundary Sb. The side surface 50S is substantially parallel to the second sub-side surface S2. The second sub-insulating structure 52 and the third sub-insulating structure 54 may include the same or different materials, covering the first sub-side surface S1 and the second sub-side surface S2. The second sub-insulating structure 52 and the third sub-insulating structure 54 each include an outer surface located on the second sub-side surface S2, and the outer surface of the second sub-insulating structure 52 and/or the third sub-insulating structure 54 can be substantially parallel to the second sub-side surface S2. In another embodiment, a thickness t1 of the first sub-insulating structure 50 is greater than both thicknesses of the second sub-insulating structure 52 and the third sub-insulating structure 54. The thickness of the first sub-insulating structure 50 is between 0.5-2 μm, and the thicknesses of the second sub-insulating structure 52 and the third sub-insulating structure is between 0.005-0.5 μm. The thickness of the second sub-insulating structure 52 can be greater than the thickness of the third sub-insulating structure 54. Both the height h and the height h1 are greater than or equal to the thickness t1. When the thicknesses of the second sub-insulating structure 52 and the third sub-insulating structure 54 are much smaller than h, the height h and the height h1 are similar. In one embodiment, the thickness of the second sub-insulating structure 52 and/or the third sub-insulating structure 54 on the second sub-side surface S2 decreases gradually as it approaches the bottom surface 12b of the semiconductor stack 12. In another embodiment, the first sub-insulating structure 50 includes a plurality of first sub-layers and a plurality of second sub-layers alternately stacked as described above (not shown), wherein the first sub-layer has a first refractive index, the second sub-layer has a second refractive index, and the first refractive index and the second refractive index are different.

In one embodiment, the third sub-insulating structure 54 is, for example, a compact layer. The compact layer can be formed, for example, by atomic layer deposition (ALD), and its thickness is between 50 Å and 2000 Å. In one embodiment, the thickness ranges between 100 Å and 1500 Å. The compact layer includes insulating material, which can be the same as one of the first sub-layer and the second sub-layer, or different from both the first sub-layer and the second sub-layer. In one embodiment, the compact layer can conformally cover the underlying structure, for example, covering the semiconductor stack 12. Due to its good step coverage characteristics, it can protect the underlying structure, such as preventing moisture from entering the semiconductor stack 12. In other embodiments (not shown), the compact layer can be located at the bottom, at the top, or between any two layers of the above-mentioned stack, the bottom layer, and the top layer of the insulating structure 5. When the compact layer is positioned at the topmost portion of the insulating structure 5, it can enhance the adhesion between the insulating structure 5 and the overlying structure (such as electrode pad, which will be described in detail later).

In one embodiment, the second sub-insulating structure 52 can be the aforementioned top layer or bottom layer, and the third sub-insulating structure 54 can be the aforementioned dense layer, but this embodiment is not limited thereto.

It should be noted that FIG. 3 is only an example. The first to third sub-insulating structures 50, 52, and 54 may be stacked in a different order than that shown in FIG. 3, or there may be two or more second sub-insulating structure 52 and/or two or more third sub-insulating structure 54, or any one of the second insulating structure 52 and the third sub-insulating structure 54 can be omitted. For example, the second sub-insulating structure 52 and/or the third sub-insulating structure 54 can be stacked on the first sub-insulating structure 50, and can cover the second sub-side surface S2 and the side surface 50S of the first sub-insulating structure 50.

FIG. 4 shows an enlarged cross-sectional view of a local area R of a light-emitting device 3 in accordance with another embodiment of the present application. In order to show the difference between the light-emitting device 3 and the light-emitting device 1, the enlarged cross-sectional view of a local area R is used for explanation. The parts of the structure of the light-emitting device 3 that are the same as those of the light-emitting device 1 are not shown in a full cross-sectional view. The difference between light-emitting device 3 and the aforementioned embodiments is that, as shown in FIG. 4, the bottom surface 12b of the semiconductor stack 12 of light-emitting device 3 includes a light extraction structure, and the light emitted from the semiconductor stack 12 can be extracted through the light extraction structure, thereby improving the brightness of the light-emitting device 3. In one embodiment, as shown in FIG. 4, the light extraction structure includes a plurality of recesses P distributed on the bottom surface 12b of the semiconductor stack 12. Each recess P has a depth d, where the depth d can be less than the height h. The shape of the recess P can be pyramid, hemisphere, cone, trench, polygonal, etc. In other embodiments (not shown), the light extraction structure includes a plurality of protrusions distributed on the bottom surface 12b of the semiconductor stack 12, which can also be pyramid, hemisphere, cone, stripe, or polygonal in shape. Nevertheless, the present embodiment is not limited thereto. The plurality of recesses P or protrusions may be distributed regularly or irregularly. In different embodiments, the protrusions may be separated or connected, and the recesses P may be separated or connected.

The manufacturing method of light-emitting device 3 is similar to that of light-emitting device 1 described above, except that, after the step of removing the substrate 10 as shown in FIG. 1G, the bottom surface 12b of the semiconductor stack 12 can be etched to form the light extraction structure. In another embodiment, during the step of forming the semiconductor stack 12 on the substrate 10 as shown in FIG. 1A, the patterned substrate as described above can be used. The light extraction structure is formed on the bottom surface 12b of the semiconductor stack 12 corresponding to the pattern structures of the patterned substrate after removing the substrate 10 in the step shown in FIG. 1G. For example, if the patterned substrate has recesses on the upper surface 10a, after removing the substrate 10, the bottom surface 12b of the semiconductor stack 12 may have corresponding protrusions as the light extraction structure. If the patterned substrate has protrusions on the upper surface 10a, after removing the substrate 10, the bottom surface 12b of the semiconductor stack 12 may have corresponding recesses P as the light extraction structure. In one embodiment, the height of the protrusion on the patterned substrate corresponds to the depth d of the recesses P. For example, when the depth d of the recess P is less than or equal to the height h, it means that the height of the protrusions on the substrate 10 is also less than or equal to the height h. In this case, it can be ensured that, during the step of forming the insulating structure 5 as shown in FIG. 1D, the insulating structure 5 formed in the ISO region and on the semiconductor stack 12 can be discontinuous, and the two are not connected via the highest point of a protrusion near the second sub-side surface S2. In another embodiment, the height of the protrusions on the patterned substrate does not correspond to the depth d of the recesses P. For example, after removing the patterned substrate 10, the bottom surface 12b of the semiconductor stack 12 can be further etched to reduce the depth d of the recesses P, or flatten the bottom surface 12b of the semiconductor stack 12.

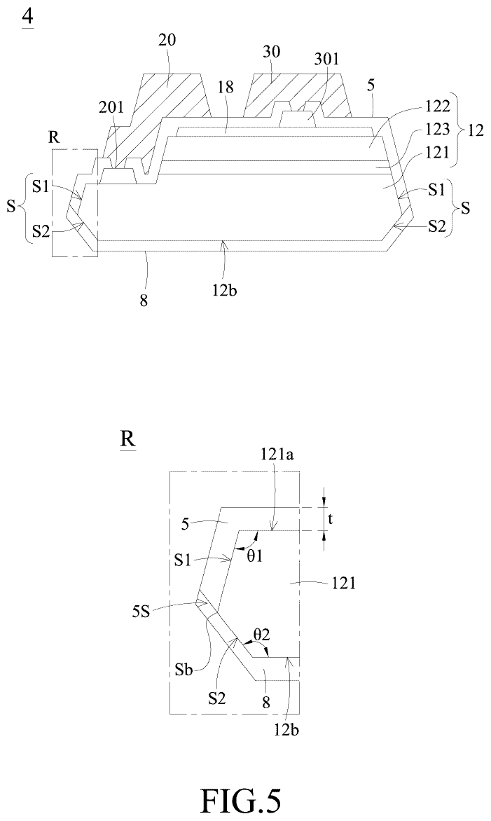

FIG. 5 shows a cross-sectional view and an enlarged view of a local area R of a light-emitting device 4 according to another embodiment of the present application. The difference between light-emitting device 4 and light-emitting device 1 is that light-emitting device 4 further includes a protective structure 8 covering the bottom surface 12b of the semiconductor stack. The manufacturing method of light-emitting device 4 is similar to that of light-emitting device 1, except that, after the step of removing the substrate 10 as shown in FIG. 1G and exposing the bottom surface 12b, the protective structure 8 may be formed on the bottom surface 12b of the semiconductor stack. In one embodiment, after removing the substrate 10, part of the first bonding layer 60 may be further removed, so that the bottom surface 12b of the semiconductor stack, the second sub-side surface S2, and the side surface 5S of the insulating structure 5 are exposed, and then a protective structure 8 is formed to cover the bottom surface 12b, the second sub-side surface S2, and the side surface 5S of the insulating structure 5. The protective structure 8 can protect the semiconductor stack 12 and the insulating structure 5, for example, to prevent the ingress of moisture through surfaces or gaps. There is an interface between the protective structure 8 and the insulating structure 5, which corresponds to the side surface 5S of the insulating structure 5. The protective structure 8 includes insulating material. The protective structure 8 can be a stack of multiple insulating layers or a single insulating layer. Its detailed structure and material can be referred to the description of the insulating structure 5 above and will not be repeated here. In one embodiment, similar to the insulating structure 5, the protective structure 8 can be a reflective structure. For example, the protective structure 8 can reflect light within a specific wavelength range, and can thus serve as a color filter. Moreover, the protective structure 8 can purify the color of the light emitted from the semiconductor stack 12, so that the full width at half maximum (FWHM) of the light extracted through the protective structure 8 is limited within a certain range. In another embodiment, the protective structure 8 can reflect light within a specific range of incident angle, thereby adjusting the emission angle and light pattern of the light-emitting device 4, increasing or decreasing the amount of light emitted in the normal direction, and concentrating or broadening the divergence angle of the light-emitting device 4. In one embodiment, the protective structure 8 comprises a distributed Bragg reflector.

In other embodiments (not shown), the protective structure 8 may cover all or part of the bottom surface 12b of the semiconductor stack 12, but does not cover the second sub-side surface S2 or the side surface 5S of the insulating structure 5.

In other embodiments (not shown), similar to FIG. 3, parts of layers in the insulating structure 5 (e.g., the second sub-insulating structure 52 and/or the third sub-insulating structure 54) may cover the second sub-side surface S2, and have a gradually decreasing thickness on the second sub-side surface S2. The protective structure 8 covers the parts of layers in the insulating structure 5 that is on the second sub-side surface S2.

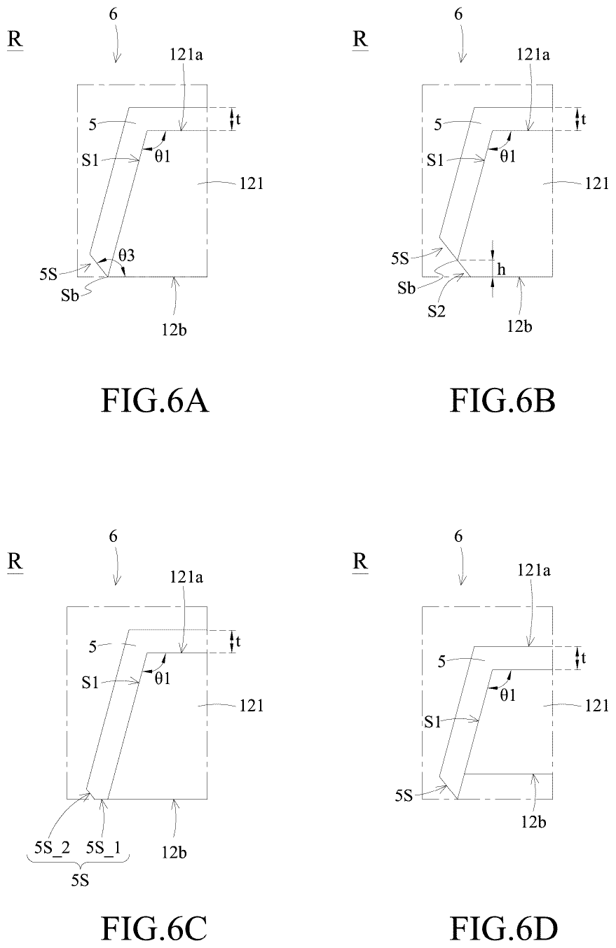

FIGS. 6A to 6D each show an enlarged cross-sectional view of a local area R of a light-emitting device 6 according to other embodiments of the present application. In order to show the difference between the light-emitting device 6 and the light-emitting device 1, the enlarged cross-sectional view of a local area R is used for explanation. The parts of the structure of the light-emitting device 6 that are the same as those of the light-emitting device 1 are not shown in a full cross-sectional view. The manufacturing method of the light-emitting device 6 is different from the embodiments described above is that, after removing the substrate 10 to expose the bottom surface 12b of the semiconductor stack as shown in FIG. 1G, a portion of the semiconductor stack 12 can be removed from the bottom surface 12b. The method for removing the portion of the semiconductor stack 12 includes etching or grinding. After this removal step, the bottom surface of the semiconductor stack is still referred to as bottom surface 12b in the present application. In one embodiment shown in FIG. 6A, the depth of removal from the bottom surface 12b of the semiconductor stack 12 may reach the boundary Sb, causing the second sub-side surface S2 to disappear, and the side surface 5S of the insulating structure 5 is not parallel to the bottom surface 12b of the semiconductor stack. A third angle θ3 between the side surface 5S and the bottom surface 12b of the semiconductor stack is less than 180 degrees; in one embodiment, θ3 may be between 150 and 170 degrees.

In another embodiment shown in FIG. 6B, the depth of removal from the bottom surface 12b of the semiconductor stack 12 does not reach the boundary Sb. The size of the second sub-side surface S2, that is reduced. In other words, the height h of the boundary Sb relative to the bottom surface 12b of the semiconductor stack 12 is reduced. In another embodiment shown in FIG. 6C, the depth of removal from the bottom surface 12b of the semiconductor stack 12 may exceed the boundary Sb, simultaneously removing part of the insulating structure 5. Therefore, as shown in FIG. 6C, in the cross-sectional view, the side surface 5S of the insulating structure 5 may be divided into multiple sections. For example, the side surface 5S includes a first section 5S_1 parallel to the bottom surface 12b of the semiconductor stack 12 and a second section 5S_2 not parallel to the bottom surface 12b.

In another embodiment shown in FIG. 6D, the depth of removal from the bottom surface 12b of the semiconductor stack 12 may exceed the boundary Sb. By controlling the etching ratio or removal rate of the semiconductor stack 12 and the insulating structure 5, the side surface 5S of the insulating structure 5 may extend beyond the bottom surface 12b of the semiconductor stack.

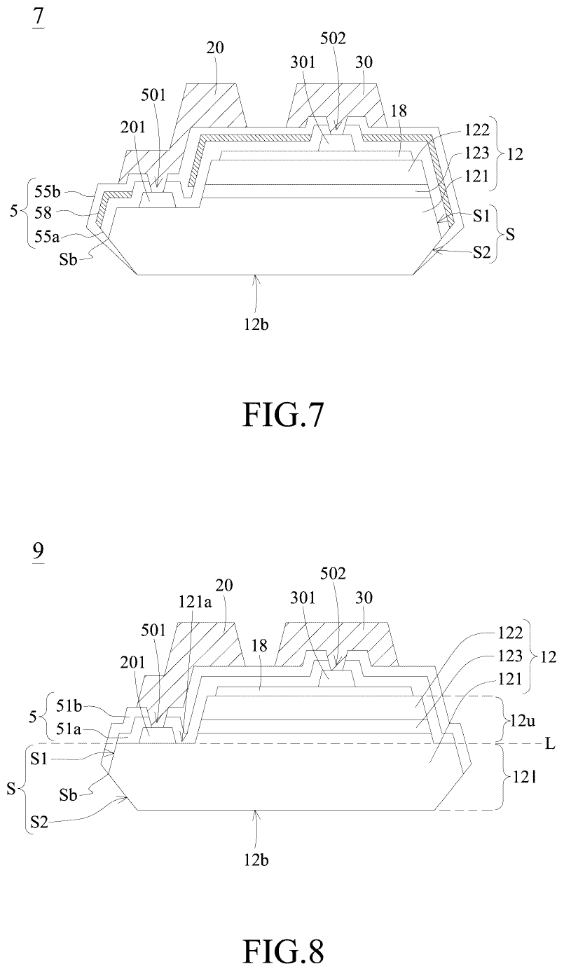

FIG. 7 shows a cross-sectional view of a light-emitting device 7 in accordance with another embodiment of the present application. The difference between light-emitting device 7 and light-emitting device 1 is that the insulating structure 5 of light-emitting device 7 includes a metal reflective layer 58. Specifically, as shown in FIG. 7, the insulating structure 5 comprises two sub-insulating structures 55a, 55b, and a metal reflective layer 58 sandwiched between them. Each of the two sub-insulating structures 55a, 55b can be selected from the aforementioned first sub-insulating structure 50, second sub-insulating structure 52, or third sub-insulating structure 54. The metal reflective layer 58 is sandwiched between the two sub-insulating structures 55a, 55b and is electrically insulated from the first electrode pad 20 and the second electrode pad 30. Specifically, the metal reflective layer 58 includes an inner surface in contact with sub-insulating structure 55a, an outer surface in contact with sub-insulating structure 55b, and a side surface connecting the inner and outer surfaces. The material of the metal reflective layer 58 includes metal with high reflectivity to the light emitted from the semiconductor stack 12, such as gold, silver, or aluminum. The metal reflective layer 58 can reflect the light emitted from the semiconductor stack 12, thereby increasing the brightness of light-emitting device 7. For example, the sub-insulating structure 55a can be the first sub-insulating structure 50, and the sub-insulating structure 55b can be the second sub-insulating structure 52. When the first sub-insulating structure 50 includes Bragg reflector, the Bragg reflector and the metal reflective layer 58 forms an omni-directional reflector (ODR).

In some different embodiments, the sub-insulating structures 55a and/or 55b may further cover the second sub-side surface S2. For example, the sub-insulating structure 55a can be the first sub-insulating structure 50, the sub-insulating structure 55b can be the second sub-insulating structure 52, and the second sub-insulating structure 52 has a gradually decreasing thickness on the second sub-side surface S2 and covers the side surface of the metal reflective layer 58 to protect it. In other embodiments, the sub-insulating structures 55a and 55b can be replaced by any one of the aforementioned first to third sub-insulating structures 50, 52, and 54. For example, sub-insulating structure 55a can be the second sub-insulating structure 52 or the third sub-insulating structure 54, and the sub-insulating structure 55a covers the second sub-side surface S2. In another embodiment (not shown), the protective structure 8 as shown in FIG. 5 can be disposed on the bottom surface 12b of the semiconductor stack 12 of light-emitting device 7.

The manufacturing method of the light-emitting device 7 is similar to that of the light-emitting device 1 described above, except that, during the step of forming the insulating structure 5 (as shown in FIG. 1D), the sub-insulating structure 55a, the metal reflective layer 58, and the sub-insulating structure 55b are sequentially formed on the semiconductor stack 12. Similarly, the metal reflective layer 58 covers the first sub-side surface S1 and can be easily broken near the boundary Sb, so that the metal reflective layer 58 does not cover the second sub-side surface S2.

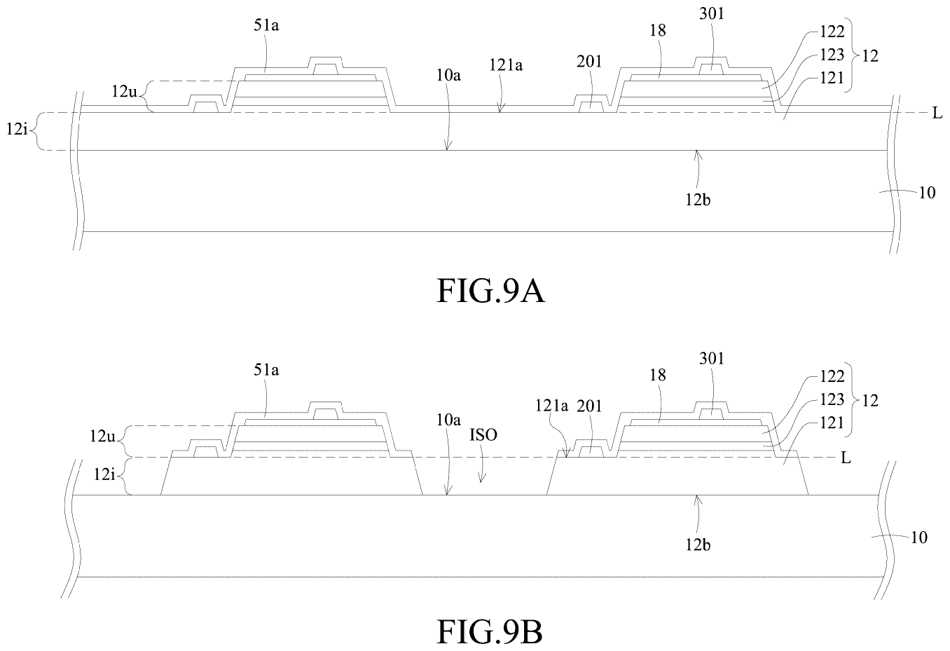

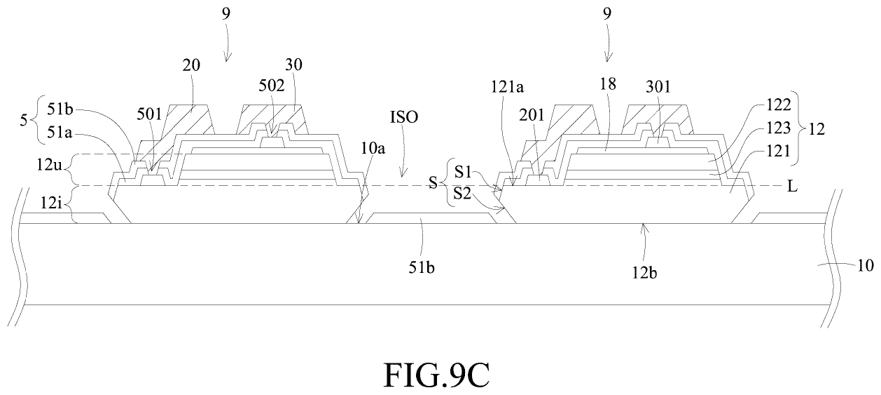

FIG. 8 shows a cross-sectional view of a light-emitting device 9 in accordance with another embodiment of the present application. The difference between light-emitting device 9 and light-emitting device 1 is that the insulating structure 5 of light-emitting device 9 comprises sub-insulating structures 51a and 51b, where the sub-insulating structure 51a covers the top surface of the semiconductor stack 12, the side surface of the upper semiconductor stack 12u, and the upper surface 121a of the first semiconductor layer 121, but does not cover the side surface S. The sub-insulating structure 51b covers both sub-insulating structure 51a and the first sub-side surface S1. In one embodiment, the sub-insulating structure 51a or 51b includes a plurality of first and second sub-layers with different refractive indices alternately stacked, as described above. FIGS. 9A to 9C show the manufacturing method for light-emitting device 9. The manufacturing method is similar to that of light-emitting device 1 except that, in the step shown in FIG. 9A, the upper surface 121a of the first semiconductor layer 121 is formed without forming the ISO region. Then, after forming the transparent conductive layer 18, the first contact electrode 201, and the second contact electrode 301 as in the aforementioned method, the sub-insulating structure 51a is formed to cover the transparent conductive layer 18, the first contact electrode 201, and the second contact electrode 301. Next, referring to FIG. 9B, part of the sub-insulating structure 51a and part of the lower semiconductor stack 121 are removed together to form the ISO region. Then, as in the manufacturing method of light-emitting device 1, the second sub-side surface S2, the sub-insulating structure 51b, and electrode pads 20 and 30 are sequentially formed as shown in FIG. 9C.

In another embodiment, the insulating structure 5 of light-emitting device 9 may be modified in reference to light-emitting device 7 described above. For example, during the step of forming the insulating structure 5 as shown in FIGS. 9B and 9C, the sub-insulating structure 55a like that in the light-emitting device 7 can be formed on the semiconductor stack 12. The difference is that, the sub-insulating structure 55a in the light-emitting device 9 only covers the top surface of the semiconductor stack 12, the side surface of the upper semiconductor stack 12u, and the upper surface 121a of the first semiconductor layer 121, followed by forming the metal reflective layer 58 and the sub-insulating structure 55b covering the first sub-side surface S1.

In other embodiments (not shown), any one of the sub-insulating structures 51a and 51b in the insulating structure 5 of light-emitting device 9 can be replaced by the metal reflective layer sandwiched between two insulating layers.

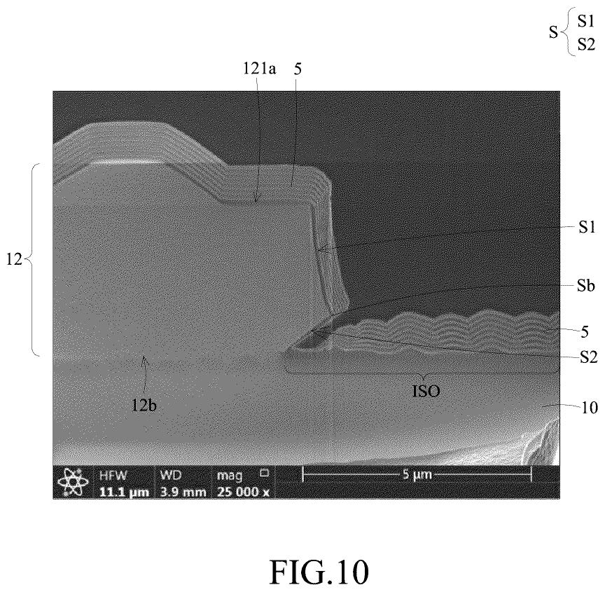

FIG. 10 shows a scanning electron microscope (SEM) image during the manufacturing method of the light-emitting device in accordance with one of the previously described embodiments of the present application. FIG. 10 shows that the insulating structure 5 covers the semiconductor stack 12, and the insulating structure 5 on the semiconductor stack 12 and the insulating structure 5 on the ISO region are discontinuous. The insulating structure 5 includes a plurality of insulating layers.

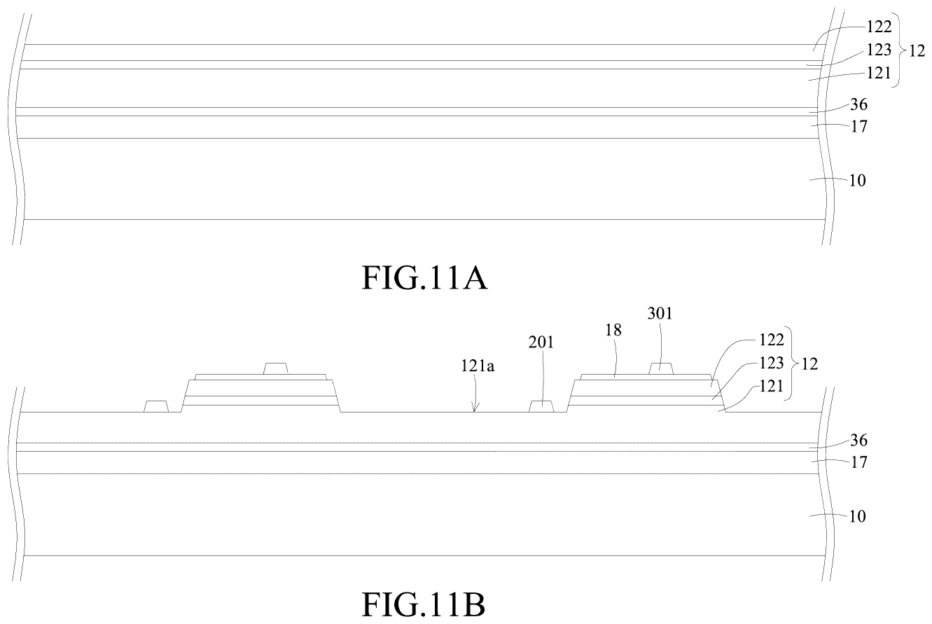

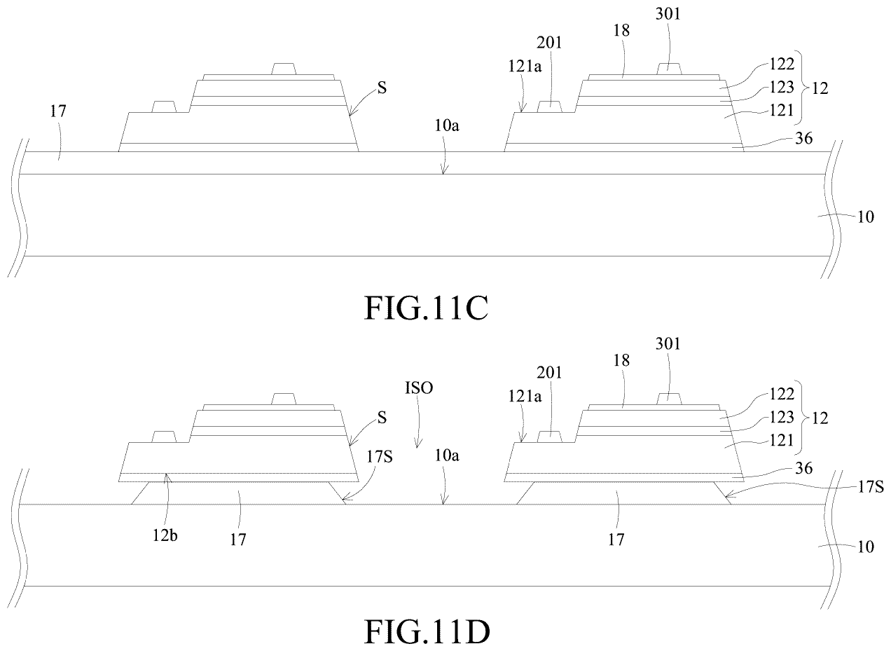

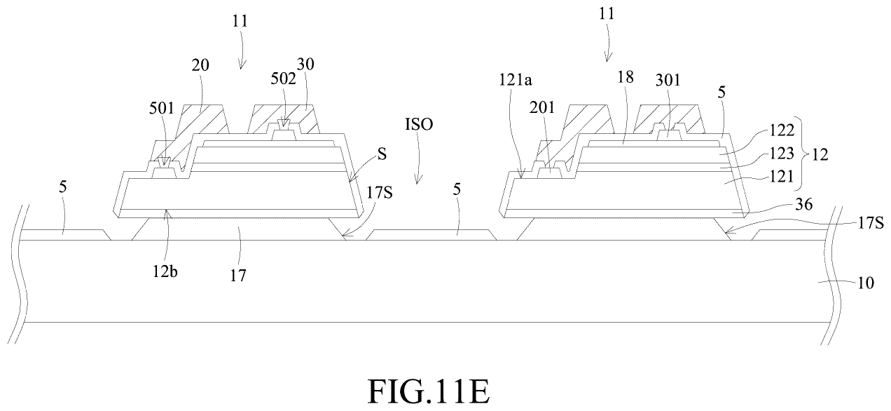

FIGS. 11A to 11E shows a manufacturing method for a light-emitting device 11 in accordance with another embodiment of the present application. First, referring to FIG. 11A, a semiconductor stack 12 is formed on a substrate 10. The semiconductor stack 12 can be initially formed on a growth substrate, and then, joined to the substrate 10 by a third bonding layer 17, and the growth substrate is removed. The substrate 10 can used as a temporary carrier for temporarily supporting the semiconductor stack 12. In one embodiment, a protective structure 36 may be first formed on the semiconductor stack 12, and then the third bonding layer 17 is formed to bond the semiconductor stack 12 to the substrate 10. The material, detailed structure and function of the third bonding layer 17 and the protective structure 36 can refer to the description of the second bonding layer 16 and the protective structure 8 described in the aforementioned embodiments and will not be repeated here. In another embodiment (not shown), the protective structure 36 is not formed, and the semiconductor stack 12 is directly bonded to the substrate 10 by the third bonding layer 17. Next, referring to FIG. 11B, part of the second semiconductor layer 122 and the active region 123 is removed to expose the upper surface 121a of the first semiconductor layer 121, and then the transparent conductive layer 18, the first contact electrode 201, and the second contact electrode 202 can be optionally formed. Next, referring to FIG. 11C, part of the first semiconductor layer 121 and the protective structure 36 is removed downward from the upper surface 121a of the first semiconductor layer to expose a surface of the third bonding layer 17, dividing the semiconductor stack 12 into a plurality of semiconductor units, and forming the side surface S of the semiconductor stack 12.

Next, referring to FIG. 11D, part of the third bonding layer 17 is further removed from the exposed surface of the third bonding layer 17 to form the ISO region. In different embodiments, depending on the depth of removal of the third bonding layer 17, the bottom of the ISO region may be the upper surface 10a of the substrate 10 or the upper surface of the thinned third bonding layer 17 remaining between the adjacent semiconductor stacks 12. The removal method may be, for example, etching. By controlling the etching conditions of the third bonding layer 17, the side surface 17S of the third bonding layer 17 is recessed beneath the semiconductor stack 12 to form an undercut. In one embodiment, on one side of the side surface 17S, a distance by which an edge of the upper surface of the third bonding layer 17 is recessed relative to the edge of the bottom surface 12b of the semiconductor stack is greater than the thickness of the insulating structure 5. In one embodiment, the recession distance is not less than 1 μm. The side surface S of the semiconductor stack 12 and the side surface 17S of the third bonding layer 17 are discontinuous and form a step.

Next, referring to FIG. 11E, like the manufacturing method of light-emitting device 1, the insulating structure 5, the first and second openings 501, 502 of the insulating structure 5, the first electrode pad 20, and the second electrode pad 30 are formed. As shown in FIG. 11E, since the side surface S of the semiconductor stack 12 and the side surface 17S of the third bonding layer 17 form a step, the insulating structure 5 can cover the side surface S of the semiconductor stack 12 and the side surface of the protective structure 36, but is not formed on the side surface 17S of the third bonding layer 17. Thus, the insulating structure 5 is broken near the side surface of the protective structure 36, and the insulating structure 5 on the ISO region and the insulating structure 5 covering the semiconductor stack 12 are discontinuous. After this step, one or more light-emitting device transferring steps may optionally be performed to separate the light-emitting devices 11 from the substrate 10. The light-emitting device 11 can be transferred and fixed onto a driving backplane of an end product (not shown), and the first and second electrode pads 20, 30 of the light-emitting device 11 are electrically connected to the circuit on the driving backplane by eutectic bonding, soldering, or conductive adhesive bonding.

In other embodiments, before performing the transferring step, both the insulating structure 5 and the remaining third bonding layer 17 in the ISO region can be removed first.

When transferring the light-emitting device 11 from the substrate 10 to another temporary carrier or to the driving backplane, since the insulating structure 5 covering the semiconductor stack 12 and the insulating structure 5 on the ISO region of the substrate 10 are discontinuous, the problem where a continuous film adheres to the top surface of the substrate and may further damage the film layer on the semiconductor stack due to pulling forces between them can be avoided, thus improving the manufacturing yield and transfer yield of the light-emitting device 11.

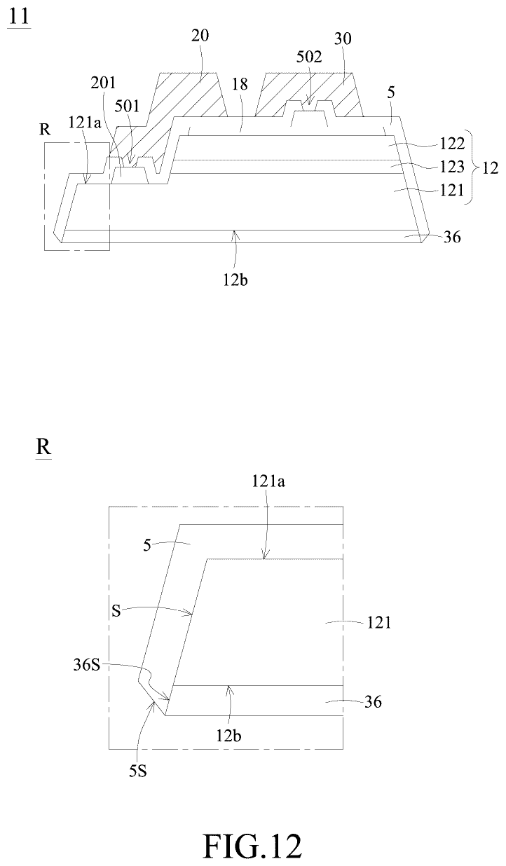

FIG. 12 shows a cross-sectional view and an enlarged view of a local region R of the light-emitting device 11 manufactured according to the above-described embodiment of the present application. As shown in FIG. 12, the protective structure 36 covers the bottom surface 12b of the semiconductor stack, including an inner surface contacting the semiconductor stack 12, an outer surface opposite to the inner surface, and a side surface 36S connecting the inner and outer surfaces. In one embodiment, the side surface 36S of the protective structure 36 is connected to the side surface S of the semiconductor stack 12 and is substantially parallel to the side surface S of the semiconductor stack. The insulating structure 5 further covers the side surface 36S of the protective structure 36. The side surface 5S of the insulating structure 5 is not parallel to the inner surface, outer surface, or bottom surface 12b of the semiconductor stack of the protective structure 36. In one embodiment, there is an interface between the protective structure 36 and the insulating structure 5, which corresponds to the side surface 36S of the protective structure 36. In one embodiment, an angle between the side surface 5S of the insulating structure 5 and the side surface 36S of the protective structure 36 is between 45 and 80 degrees.

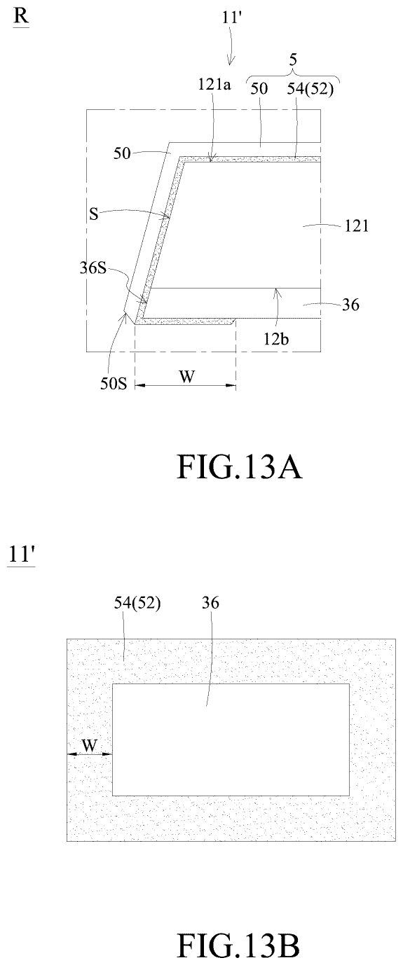

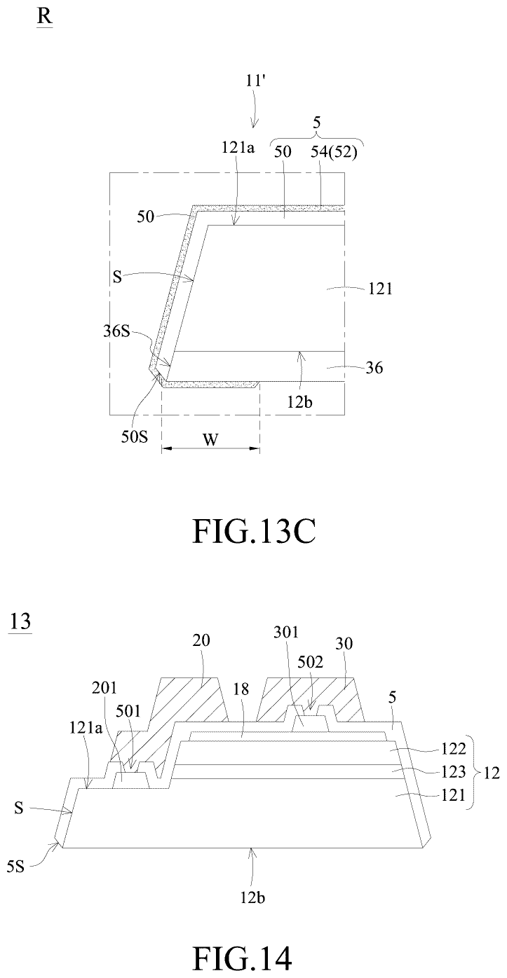

FIG. 13A shows an enlarged view of a local region R in a cross-section of a light-emitting device 11′ in accordance with a modified embodiment of the present application. FIG. 13B shows a plan view of light-emitting device 11′ viewing from a light-emitting surface, that is, from the bottom surface 12b of the semiconductor stack 12. In order to show the difference between the light-emitting device 11′ and the light-emitting device 11, the enlarged cross-sectional view of a local area R is used for explanation. The parts of the structure of the light-emitting device 11′ that are the same as those of the light-emitting device 11 are not shown in a full cross-sectional view. The difference between light-emitting device 11′ and light-emitting device 11 is that the insulating structure 5 of light-emitting device 11′ comprises the first sub-insulating structure 50 and one of the second sub-insulating structure 52 and the third sub-insulating structure 54. In one embodiment, as shown in FIG. 13A, the third sub-insulating structure 54 (and/or the second sub-insulating structure 52) is located between the first sub-insulating structure 50 and the semiconductor stack 12. The third sub-insulating structure 54 (and/or the second sub-insulating structure 52) covers the side surface S of the semiconductor stack 12, the side surface 36S of the protective structure 36, and part of the outer surface of the protective structure 36. For example, as shown in FIG. 13B, the third sub-insulating structure 54 (and/or the second sub-insulating structure 52) covers the outer surface surrounding the protective structure 36. In one embodiment, a width W over which the third sub-insulating structure 54 (and/or the second sub-insulating structure 52) covers the outer surface of the protective structure 36 is not less than 1 μm. In another embodiment, W is not less than the thickness of the insulating structure 5. The side surface 50S of the first sub-insulating structure 50 is not parallel to the inner surface and/or the outer surface of the protective structure 36, or a bottom surface 12b of the semiconductor stack 12.

In another embodiment shown in FIG. 13C, the first sub-insulating structure 50 is located between the third sub-insulating structure 54 (and/or the second sub-insulating structure 52) and the semiconductor stack 12. The third sub-insulating structure 54 (and/or the second sub-insulating structure 52) covers the first sub-insulating structure 50 and its side surface 50S, and further continuously covers the outer surface of the protective structure 36. For example, similar to that shown in FIG. 13B, the third sub-insulating structure 54 (and/or the second sub-insulating structure 52) covers the outer surface surrounding the protective structure 36.

FIG. 14 shows a cross-sectional view of a light-emitting device 13 in accordance with another embodiment of the present application. The difference between light-emitting device 13 and light-emitting device 11 is that light-emitting device 13 does not have a protective structure 36. In the manufacturing method of light-emitting device 13, in the step shown in FIG. 11A, no protective structure 36 is formed between the semiconductor stack 12 and the third bonding layer 17, and the semiconductor stack 12 is directly joined to the third bonding layer 17. In one embodiment, an angle between the side surface 5S of the insulating structure 5 and the side surface S of the semiconductor stack is between 20-80 degrees. In one embodiment, the angle is between 20-60 degrees. In another embodiment (not shown), the insulating structure 5 of light-emitting device 13 comprises the first sub-insulating structure 50 and one of the second sub-insulating structure 52 and the third sub-insulating structure 54. Therefore, similar to FIGS. 13A and 13B, the second sub-insulating structure 52 and/or the third sub-insulating structure 54 cover the side surface S of the semiconductor stack 12 and part of the bottom surface 12b of the semiconductor stack 12. For example, in a plan view, the second sub-insulating structure 52 and/or third sub-insulating structure 54 cover and contact a periphery of the bottom surface 12b.

It will be apparent to those having ordinary skill in the art that various modifications, combinations and variations can be made to the devices in accordance with the present disclosure without departing from the scope or spirit of the disclosure. For example, the stacking sequence of the semiconductor stack 12 shown in FIG. 11A is not limited thereto. The semiconductor stack 12 may, from the substrate 10 upward, sequentially include the second semiconductor layer 122, the active region 123, and the first semiconductor layer 121, with the third bonding layer 17 positioned between the second semiconductor layer 122 and the substrate 10. Then, in the step of removing part of the semiconductor stack 12 as shown in FIG. 11B, part of the first semiconductor layer 121 and the active region 123 may be removed to expose the upper surface of the second semiconductor layer 122. Accordingly, the first contact electrode 201, the second contact electrode 202, the first electrode pad 20, and the second electrode pad 30 electrically connected to each corresponding semiconductor stack 12 are also arranged opposite to those in the light-emitting device 11. For example, the insulating structure 5 of the light-emitting devices 11, 11′, and 13 may include a metal reflective layer as shown in FIG. 7, sandwiched between two insulating layers to form an omni-directional reflector. For example, the light-emitting devices 11, 11′, and 13 can be modified with reference to the light-emitting device 9 as shown in FIG. 8, such that the insulating structure 5 of the light-emitting devices 11, 11′, and 13 comprises the sub-insulating structure 51a and the sub-insulating structure 51b. The sub-insulating structure 51a covers the top surface of the semiconductor stack 12, the side surface of the upper semiconductor stack 12u, and the upper surface 121a of the first semiconductor layer 121, but does not cover the side surface S, and the sub-insulating structure 51b covers both sub-insulating structure 51a and the side surface S. Any one of the sub-insulating structures 51b or 51a can be replaced by a metal reflective layer sandwiched between two insulating layers, or by a stack formed by alternately stacking a plurality of first and second sub-layers with different refractive indices. For example, the bottom surface 12b of the semiconductor stack of light-emitting device 4 as shown in FIG. 5 may be arc-shaped, and the protective structure 8 covers the arc-shaped surface.

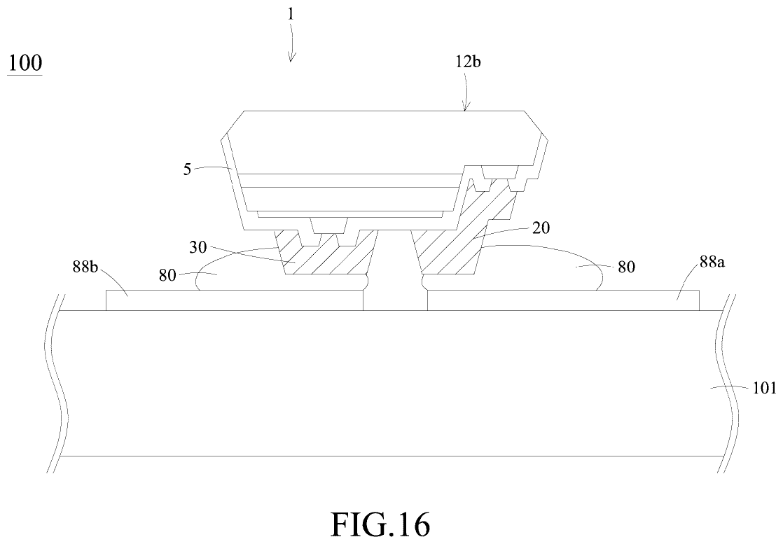

FIG. 16 shows a cross-sectional view of a light-emitting module 100 in accordance with an embodiment of the present application. The light-emitting module 100 comprises a circuit board 101, which is provided with a circuit (not shown) and circuit bonding pads 88a and 88b. The light-emitting devices in accordance with any one of the embodiments disclosed in the present application can be bonded to the circuit bonding pads 88a and 88b by a conductive bonding layer 80 in a flip-chip manner. In some embodiments, the bonding method includes, eutectic bonding, solder bonding, or adhesive bonding. The conductive bonding layer 80 can be an eutectic metal, solder metal, or conductive glue, etc. In FIG. 16, only light-emitting device 1 is shown as an example. In a plan view (not shown), the light-emitting device according to any embodiment of the present application has a diagonal length between 5˜200 μm. The size of the light-emitting device disclosed in the present application is not limited thereto.

In various applications, the light-emitting module 100 can be used as a display module or a lighting module. The light-emitting module 100 includes a plurality of light-emitting devices arranged on the circuit board 101. The circuit provided on the circuit board 101 includes active electronic components, such as transistors, and is electrically connected to the plurality of circuit bonding pads 88a and 88b to drive the plurality of light-emitting devices. In one embodiment in which the light-emitting module 100 is used as a display module, each light-emitting device can serve as a sub-pixel, and a wavelength conversion element (not shown) can be provided so that each sub-pixel emits light of different colors, and adjacent sub-pixels form a pixel unit. The wavelength conversion element includes quantum dots, phosphors, or color filters. In another embodiment, the light-emitting devices in one pixel unit include semiconductor stacks 12 with different materials so that the light-emitting device emit light with different color.

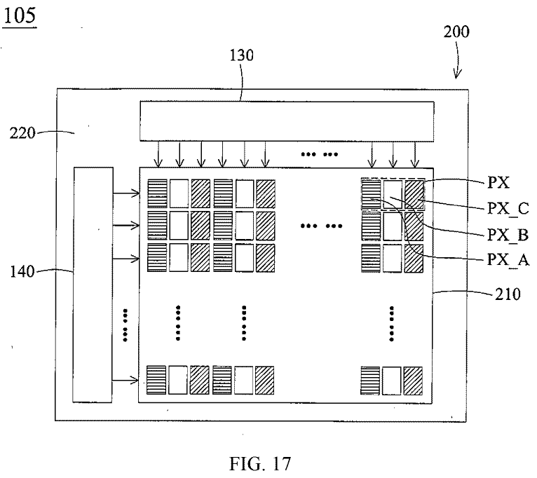

FIG. 17 shows a schematic diagram of a display module 105 which includes the light-emitting device in accordance with any embodiments of the present application. As shown in FIG. 17, the display module 105 includes a display substrate 200. The display substrate 200 includes a display area 210 and a non-display area 220, and a plurality of pixels PX are arranged on the display area 210 of the display substrate 200. Each pixel PX includes a first sub-pixel PX_A, a second sub-pixel PX_B, and a third sub-pixel PX_C. The non-display area 220 is provided with a data line driving circuit 130 and a scan line driving circuit 140. The data line driving circuit 130 connects to the data lines (not shown) of each pixel PX to transmit data signals to each pixel PX. The scan line driving circuit 140 connects to the scan lines (not shown) of each pixel PX to transmit scan signals to each pixel PX. Each pixel PX includes a light-emitting device in accordance with any of the above embodiments. Each sub-pixel emits light of a different color. In one embodiment, the first sub-pixel PX_A, the second sub-pixel PX_B, and the third sub-pixel PX_C are, for example, red, green, and blue sub-pixels, respectively. Light-emitting devices emitting light with different wavelengths can be selected as the sub-pixels so that the sub-pixel show different colors. Through the combination of red, green, and blue light emitted from the sub-pixels, the display module 105 shows full-color images.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A semiconductor device, comprising:
a semiconductor stack, comprising an upper surface, a bottom surface and a side surface,
wherein:
the side surface comprises a first sub-side surface and a second sub-side surface;
a first angle is formed between the first sub-side surface and the upper surface, the first angle is a right angle or an obtuse angle; and
the second sub-side surface is connected to the bottom surface and a second angle is formed between the second sub-side surface and the bottom surface, the second angle is an obtuse angle; and
an insulating structure, covering the semiconductor stack;
wherein the insulating structure comprises a first sub-insulating structure and a second sub-insulating structure;
wherein the first sub-insulating structure covers the upper surface and the first sub-side surface, and does not cover the second sub-side surface; and
wherein the second sub-insulating structure covers the upper surface, the first sub-side surface and the second sub-side surface.

2. The semiconductor device of claim 1, wherein the first sub-insulating structure comprises a first side surface located on the first sub-side surface, and the first side surface is substantially parallel to the second sub-side surface.

3. The semiconductor device of claim 2, wherein the second sub-insulating structure comprises an outer surface located on the second sub-side surface, and the outer surface is substantially parallel to the second sub-side surface.

4. The semiconductor device of claim 1, wherein the second sub-insulating structure comprises a thickness on the second sub-side surface, and the thickness gradually decreases as it approaches the bottom surface.

5. The semiconductor device of claim 1, wherein a thickness of the first sub-insulating structure is greater than a thickness of the second sub-insulating structure.

6. The semiconductor device of claim 5, wherein the thickness of the first sub-insulating structure is between 0.5-2 μm, and the thickness of the second sub-insulating structure is between 0.005-0.5 μm.

7. The semiconductor device of claim 1, wherein the second sub-insulating structure is closer to the semiconductor stack than the first sub-insulating structure.

8. The semiconductor device of claim 1, wherein the first sub-insulating structure comprises a plurality of first sub-layers and a plurality of second sub-layers alternately stacked, and the first sub-layer and the second sub-layer have different refractive indices.

9. The semiconductor device of claim 8, wherein a material of the second sub-insulating structure is different from a material of the first sub-layers and/or a material of the second sub-layers.

10. A semiconductor device, comprising:
a semiconductor stack, comprising an upper surface, a bottom surface and a side surface;
wherein:
the side surface comprises a first sub-side surface and a second sub-side surface;
a first angle is formed between the first sub-side surface and the upper surface, the first angle is a right angle or an obtuse angle; and
the second sub-side surface is connected to the bottom surface and a second angle is formed between the second sub-side surface and the bottom surface, the second angle is an obtuse angle; and
an insulating structure, covering the semiconductor stack, comprising a first sub-insulating structure;
wherein:
the first sub-insulating structure covers the upper surface and the first sub-side surface, and does not cover the second sub-side surface; and
the first sub-insulating structure comprises a first side surface located on the first sub-side surface, the first side surface is substantially parallel to the second sub-side surface.

11. The semiconductor device of claim 1, wherein the bottom surface comprises a light extraction structure.

12. The semiconductor device of claim 11, wherein the light extraction structure comprises a plurality of recesses and one of the recesses comprises a depth;
wherein the first sub-side surface and the second sub-side surface are connected at a boundary, and a vertical distance of the boundary to the bottom surface is greater than or equal to the depth.

13. The semiconductor device of claim 10, wherein the first sub-side surface and the second sub-side surface are connected at a boundary, and a vertical distance of the boundary to the bottom surface is greater than or equal to a thickness of the first sub-insulating structure.

14. The semiconductor device of claim 10, wherein in a plan view, the light-emitting device comprises a diagonal length between 5-200 μm.

15. The semiconductor device of claim 10, further comprising a protective structure covering the bottom surface and the first side surface of the first sub-insulating structure.

16. The semiconductor device of claim 10, further comprising an electrode pad located on the insulating structure;
wherein the insulating structure comprises an opening, and the electrode pad fills the opening and is electrically connected to the semiconductor stack.

17. The semiconductor device of claim 16, further comprising a contact electrode located between the insulating structure and the semiconductor stack, wherein the opening exposes the contact electrode.

18. The semiconductor device of claim 10, wherein the first sub-insulating structure comprises a plurality of first sub-layers and a plurality of second sub-layers alternately stacked, and the first sub-layer and the second sub-layer have different refractive indices.

19. The semiconductor device of claim 18, wherein the insulating structure further comprises a second sub-insulating structure covering the upper surface, the first sub-side surface and the second sub-side surface.

20. The semiconductor device of claim 19, wherein the second sub-insulating structure contacts the semiconductor stack.
